(19) United States
(12) Patent Application Publication
(10) Pub. No.: US 2007/0069302 A1
(43) Pub. Date: Mar. 29, 2007

(54) Method of fabricating CMOS devices having a single work function gate electrode by band gap engineering and article made thereby

(76) Inventors: Been-Yih Jin, Lake Oswego, OR (US); Robert S. Chau, Beaverton, OR (US); Brian S. Doyle, Portland, OR (US); Jack T. Kavalieros, Portland, OR (US); Suman Datta, Beaverton, OR (US); Mark L. Doczy, Beaverton, OR (US); Matthew V. Metz, Hillsboro, OR (US); Justin K. Brask, Portland, OR (US)

Correspondence Address: INTEL/BLAKELY, 12400 WILSHIRE BOULEVARD, SEVENTH FLOOR, LOS ANGELES, CA, 90025-1030, US

(21) Appl. No.: 11/238,445

(22) Filed: Sep. 28, 2005

(51) Int. Cl. H01L 29/78; H01L 21/8238

(52) U.S. Cl. 257/369; 438/478; 438/509; 438/199

(57) ABSTRACT

A method utilizing a common gate electrode material with a single work function for both the pMOS and nMOS transistors where the magnitude of the transistor threshold voltages is modified by semiconductor band engineering and article made thereby.

### RELATED APPLICATIONS

This application relates to the application entitled “CMOS devices with a Single Work Function Gate Electrode and Method of Fabrication,” filed on Sep. 28, 2005.

### BACKGROUND OF THE INVENTION

1. Field of the Invention

The present invention relates to the field of semiconductor integrated circuit manufacturing, and more particularly to CMOS (complementary metal oxide semiconductor) devices having gate electrodes with a single work function.

2. Discussion of Related Art

During the past two decades, the physical dimensions of MOSFETs have been aggressively scaled for low-power, high-performance CMOS applications. In order to continue scaling future generations of CMOS, the use of metal gate electrode technology is important. For example, further gate insulator scaling will require the use of dielectric materials with a higher dielectric constant than silicon dioxide. Devices utilizing such gate insulator materials demonstrate vastly better performance when paired with metal gate electrodes rather than traditional poly-silicon gate electrodes.

Depending on the design of the transistors used in the CMOS process, the constraints placed on the metal gate material are somewhat different. For a planar, bulk or partially depleted, single-gate transistor, short-channel effects (SCEs) are typically controlled through channel dopant engineering. Requirements on the transistor threshold voltages then dictate the gate work-function values must be close to the conduction and valence bands of silicon. For such devices, a “mid-gap” work function gate electrode that is located in the middle of the p and n channel work function range is inadequate. A mid-gap gate electrode typically results in a transistor having either a threshold voltage that is too high for high-performance applications, or compromised SCEs when the effective channel doping is reduced to lower the threshold voltage. For non-planar or multi-gate transistor designs, the device geometry better controls SCEs and the channel may then be more lightly doped and potentially fully depleted at zero gate bias. For such devices, the threshold voltage can be determined primarily by the gate metal work function. However, even with the multi-gate transistor's improved SCEs, it is typically necessary to have a gate electrode work function about 250 meV below mid-gap for an nMOS transistor and about 250 meV above mid-gap for a pMOS transistor. Therefore, a single mid-gap gate material is also incapable of achieving low threshold voltages for both pMOS (a MOSFET with a p-channel) and nMOS (a MOSFET with an n-channel) multi-gate transistors.

For these reasons, CMOS devices generally utilize two different gate electrodes, an nMOS electrode and a pMOS electrode, having two different work function values. For the traditional polysilicon gate electrode, the work function values are typically about 4.2 and 5.2 electron volts for the nMOS and pMOS electrodes respectively, and they are generally formed by doping the polysilicon material to be either n or p type. Attempts at changing the work function of metal gate materials to achieve similar threshold voltages is difficult as the metal work function must either be varied with an alloy mixture or two different metals utilized for n and p-channel devices.

One such conventional CMOS device 100 is shown in FIG. 1, where insulating substrate 102, having a carrier 101 and an insulator 103, has a pMOS transistor region 104 and an NMOS transistor region 105. The pMOS device 104 is comprised of a non-planar semiconductor body 106 having a source 116 and a drain 117, a gate insulator 112 and a gate electrode 113 made of a “p-metal” (a metal having a work function appropriate for a low pMOS transistor threshold voltage). The nMOS device 105 is comprised of a non-planar semiconductor body 107 having a source 116 and a drain 117, a gate insulator 112 and a gate electrode 114 made of an “n-metal” (a metal having a work function appropriate for a low nMOS transistor threshold voltage). While fabricating transistors having gate electrodes made of two different materials is prohibitively expensive, simpler approaches to dual-metal gate integration like work-function engineering of the metal film suffer from problems such as poor reliability and insufficient work-function shift.

### BRIEF DESCRIPTION OF THE DRAWINGS

FIG. 1 is an illustration of a perspective view of conventional non-planar transistors on an insulating substrate and conventional gate electrodes.

FIG. 2A is an illustration of a perspective view of non-planar transistors on an insulating substrate and gate electrodes in accordance with the present invention.

FIG. 2B is an illustration of a perspective view of non-planar transistors on a bulk substrate and gate electrodes in accordance with the present invention.

FIGS. 3A-3F are illustrations of perspective views of non-planar transistors on an insulating substrate with gate electrodes in accordance with the present invention.

FIGS. 4A-4H are illustrations of perspective views of non-planar transistors on a bulk substrate with gate electrodes in accordance with the present invention.

FIGS. 5A-5C are illustrations of perspective views of a method of fabricating non-planar bodies for transistors in accordance with the present invention.

### DETAILED DESCRIPTION OF THE PRESENT INVENTION

A novel device structure and its method of fabrication are described. In the following description, numerous specific details are set forth, such as specific materials, dimensions and processes, etc. in order to provide a thorough understanding of the present invention. In other instances, well-known semiconductor processes and manufacturing techniques have not been described in particular detail in order to not unnecessarily obscure the present invention.

Embodiments of the present invention include complementary (pMOS and nMOS) transistors having semiconductor channel regions which have been band gap engineered to achieve a low threshold voltage. In particular embodiments, the complementary devices utilize the same material having a single work function as the gate electrode. Engineering the band gap of the semiconductor transistor channels rather than engineering the work function of the transistor gate metal for the individual pMOS and nMOS devices avoids the manufacturing difficulties associated with depositing and interconnecting two separate gate metals in a dual-metal gate process. A single metal gate stack, used for both pMOS and nMOS transistors, simplifies fabrication while engineering the band gap of the semiconductor transistor channels enables independent tuning of the pMOS and nMOS threshold voltages. In embodiments of the present invention, the threshold voltage of a device can be targeted through the use of semiconductor materials that have an appropriate valance band (nMOS) or conduction band (pMOS) offset relative to the substrate. Therefore, embodiments of the present invention can utilize a single mid-band gap metal for both the pMOS and nMOS transistors in a CMOS device while still achieving a low threshold voltage for both the pMOS and nMOS transistors.

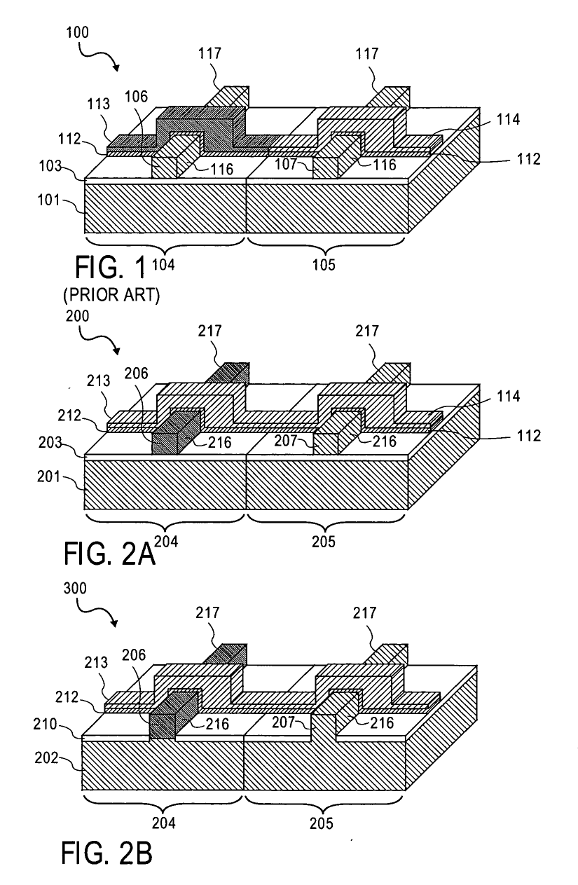

An example of a CMOS device 200 with a metal gate structure and an engineered band gap in accordance with an embodiment of the present invention is illustrated in FIG. 2A. Although FIG. 2A shows a tri-gate embodiment of the present invention, it should be appreciated that additional embodiments comprising single-gate or multi-gate transistors (such as dual-gate, FinFET, omega-gate) designs are also possible. CMOS device 200 comprises a transistor of a first conductivity type on a first region 204 and a transistor of a complementary conductivity type on a second region 205 of substrate 202. In embodiments of the present invention, as depicted in both FIGS. 2A and 2B, at least a portion of the semiconductor body 206 is formed on a region of the semiconductor substrate that has been alloyed with an epitaxial film and thus has a narrower band gap than the semiconductor body 207. The narrow band gap semiconductor alloy will then reduce the effective threshold voltage of a pMOS transistor in region 204 by an amount approximately equal to the conduction band offset between the semiconductor alloy used for body 206 and a non-alloyed semiconductor body 207 in region 205. Similarly, in other embodiments, a valence band offset between the alloyed semiconductor material of transistor body 206 and the unalloyed semiconductor material of transistor body 207 modifies the effective threshold voltage of an nMOS transistor. In a further embodiment, a semiconductor body having a larger band gap can be used to increase either a pMOS or an nMOS transistor's threshold voltage by the respective band offset relative to the unalloyed substrate on which the transistors are formed in order to reduce transistor leakage or increase a transistor's breakdown voltage.

In alternate embodiments of the present invention (not shown) both the pMOS transistor and nMOS transistor channels are formed on an alloyed semiconductor substrate material. When both alloyed semiconductor regions have only a conduction band offset (no valence band offset) relative to the unalloyed substrate regions, the band gap engineered alloyed semiconductor region of the nMOS transistor will not have any effect on the nMOS threshold voltage.

In a particular embodiment of the present invention, as shown in FIG. 2A, CMOS device 200 includes non-planar monocrystalline semiconductor bodies 206 and 207 on insulating layer 203 over carrier 201. In certain embodiments of the present invention, bodies 206 and 207 are formed from a semiconductor film on an insulator 203 over a carrier 201. Semiconductor bodies 206 and 207 can be formed of any well-known semiconductor material, such as silicon (Si), gallium arsenide (GaAs), indium antimonide (InSb), gallium antimonide (GaSb), gallium phosphide (GaP), or indium phosphide (InP). For embodiments where monocrystalline silicon is formed on insulator 203, the structure is commonly referred to as silicon/semiconductor-on-insulator, or SOI, substrate. In an embodiment of the present invention, the semiconductor film on insulator 203 is comprised of a monocrystalline silicon semiconductor doped with either p-type or n-type conductivity with a concentration level between 1×10¹⁶-1×10¹⁹ atoms/cm³. In another embodiment of the present invention, the semiconductor film formed on insulator 203 is comprised of a silicon semiconductor substrate having an undoped, or intrinsic epitaxial silicon region. Insulator 203 can be any dielectric material and carrier 201 can be any well-known semiconductor, insulator or metallic material.

In another embodiment of the invention, as shown in device 300 of FIG. 2B, a “bulk” substrate is used and semiconductor bodies 206 and 207 are formed on an upper region of the “bulk” semiconductor substrate. In an embodiment of the present invention, the substrate 202 is comprised of a silicon semiconductor substrate having a doped epitaxial silicon region with either p-type or n-type conductivity with a concentration level between 1×10¹⁶-1×10¹⁹ atoms/cm³. In another embodiment of the present invention, the substrate 202 is comprised of a silicon semiconductor substrate having an undoped, or intrinsic epitaxial silicon region. In bulk substrate embodiments of the present invention, isolation regions 210 are formed on the bulk, monocrystalline, semiconductor and border the semiconductor bodies 206 and 207, as shown in FIG. 2B. In some embodiments, at least a portion of the sidewalls of the bodies 206 and 207 extend above the bordering isolation regions 210. In other embodiments, such as for planar single-gate designs, the semiconductor bodies 206 and 207 have only a top surface exposed.

In the embodiments shown in FIGS. 2A and 2B, semiconductor bodies 206 and 207 have a pair of opposite sidewalls separated by a distance defining an individual semiconductor body width. Additionally, semiconductor bodies 206 and 207 have a top surface opposite a bottom surface formed over the substrate. In embodiments with an insulating substrate, semiconductor bodies 206 and 207 are in contact with the insulating layer shown in FIG. 2A. In embodiments with a bulk substrate, semiconductor bodies 206 and 207 are in contact with the bulk semiconductor substrate and the bottom surface of the body is considered to be planar with the bottom surface of the isolation region 210 bordering the body, as shown in FIG. 2B. The distance between the top surface and the bottom surface defines an individual semiconductor body height. In an embodiment of the present invention, the individual body height is substantially equal to the individual semiconductor body width. In a particular embodiment of the present invention, the semiconductor bodies 206 and 207 have a width and height less than 30 nanometers, and more particularly, less than 20 nanometers. In another embodiment of the present invention, the individual semiconductor body height is between half the individual semiconductor body width and twice the individual semiconductor body width. In still other embodiments of the present invention, a planar or single-gate transistor design (not shown) is formed on the substrate so that a gate dielectric and a gate electrode are formed only on a top surface of the semiconductor regions.

In an embodiment of the present CMOS invention, the alloyed semiconductor body 206 is single crystalline to ensure sufficient carrier lifetime and mobility. Semiconductor body 206 can be formed of any well-known semiconductor material, such as silicon germanium (SiGe), silicon carbide (SiC), indium gallium arsenide (InₓGa₁₋ₓAs_{y}), indium antimonide (InₓSb_{y}), indium gallium phosphide (InₓGa₁₋ₓP_{y}), or carbon nanotubes (CNT). In certain embodiments of the present invention, the semiconductor body 206 is an alloy of silicon and germanium (SiGe). In certain other embodiments, one semiconductor body is an alloy of silicon and carbon (SiC).

Embodiments of the present invention include decreasing the conduction band energy of a pMOS transistor having a SiGe channel region by increasing the concentration of the germanium. In this manner, it is possible to fabricate both a pMOS and nMOS multi-gate transistor having gate electrodes of the same material and threshold voltage magnitudes less than 0.7 V over a range of transistor channel doping levels. As the conduction band energy decreases, the threshold voltage is lowered by an amount approximately equal to the conduction band voltage offset. In an embodiment of the present invention, the germanium concentration of the alloyed region is between 5 and 50 percent, and more particularly, between 15 and 30 percent. For embodiments having about 25 percent germanium, the conduction band energy is decreased by about 300 meV below the conduction band of silicon. Thus, a pMOS device having a SiGe channel region comprised of about 25 percent germanium will have a threshold voltage magnitude approximately 300 meV less than that of a pure silicon channel.

In embodiments of the present invention, nMOS multi-gate devices have a work function difference (the difference between the gate metal work function an the semiconductor work function or (φₘₑₜₐₗ-φ_{semiconductor}) of about 0.4 eV while the work function difference for a pMOS multi-gate device is about 0.7 eV. In a particular embodiment of the present invention, the 0.4 eV nMOS work function difference is achieved through Fermi-level pinning a mid-gap titanium nitride metal gate material (having a work function of about 4.7 eV). In a further embodiment of the present invention, a 0.7 eV pMOS work function difference is achieved with a band-engineered SiGe channel region comprised of about 25 percent germanium. The 25 percent germanium decreases the channel semiconductor conduction band energy and, in effect, shifts the work function difference of the mid-gap titanium nitride metal gate material by about 300 mV, from the pinned Fermi-level of 0.4 eV to the desired 0.7 eV.

Embodiments of the present invention include adjusting the germanium concentration of a pMOS SiGe body to adjust the threshold voltage, enabling multiple threshold voltages on the same chip, which is a different challenge from setting a single threshold voltage to match an nMOS device. For ULSI systems, it is typically necessary to provide a menu of devices with different threshold voltages to allow for the optimization of performance and power consumption. The ability to tune the threshold voltage by about 150 mV is often required. For devices with geometries in the sub-50-nm gate-length regime, it is very difficult to achieve such a range by merely doping the transistor channel. Disadvantageous channel doping can by avoided by embodiments of the present invention where a first pMOS device has a channel comprised of a first germanium concentration targeting a first threshold voltage while a second pMOS device has a channel comprised of a second germanium concentration targeting a second threshold voltage.

As shown in FIGS. 2A and 2B, CMOS devices 200 and 300, respectively, have a gate insulator layer 212. In the depicted embodiments, gate insulator 212 surrounds the semiconductor bodies 206 and 207. In such tri-gate embodiments, gate dielectric layer 212 is formed on the sidewalls as well as on the top surfaces of the semiconductor bodies 206 and 207, as shown in FIGS. 2A and 2B. In other embodiments, such as in FinFET or dual-gate designs, gate dielectric layer 212 is only formed on the sidewalls of the semiconductor bodies 206 and 207. Gate insulator 212 can be of any commonly known dielectric material compatible with the semiconductor bodies and the gate electrode 213. In an embodiment of the present invention, the gate dielectric layer is a silicon dioxide (SiO₂), silicon oxynitride (SiOₓN_{y}) or a silicon nitride (Si₃N₄) dielectric layer. In one particular embodiment of the present invention, the gate dielectric layer 212 is a silicon oxynitride film formed to a thickness of between 5-20 Å. In another embodiment of the present invention, gate dielectric layer 212 is a high K gate dielectric layer, such as a metal oxide dielectric, such as to tantalum oxide, titanium oxide, hafnium oxide, zirconium oxide, or aluminum oxide. Gate dielectric layer 212 can also be other types of high K dielectric, such as lead zirconium titanate (PZT).

CMOS devices 200 and 300 have a gate electrode 213, as shown in FIGS. 2A and 2B, respectively. In certain embodiments, gate electrode 213 is formed on gate dielectric layer 212 over the sidewalls of each of the semiconductor bodies 206 and 207. Gate electrode 213 has a pair of laterally opposite sidewalls separated by a distance, defining the gate length (L_{g}) of transistors in region 204 and 205. In certain embodiments of the present invention, where the transistors in regions 204 and 205 are planar or single-gate devices (not shown), the gate electrode is merely on a top surface of the gate insulator over the semiconductor substrate. In the embodiments of the present invention, as shown in FIGS. 2A and 2B, the same material is used to form the gate electrode 213 for pMOS device in region 204 and nMOS device in region 205. In this manner, CMOS device fabrication can be greatly simplified because there is no need for the pMOS device to have a gate metal with a different work function than that of the nMOS device. In further embodiments of the present invention, the same gate electrode structure physically connects a pMOS device to an nMOS device. Gate electrode 213 of FIGS. 2A and 2B can be formed of any suitable gate electrode material having the appropriate work function. In an embodiment of the present invention, the gate electrode is a metal gate electrode, such as tungsten, tantalum nitride, titanium nitride or titanium silicide, nickel silicide, or cobalt silicide. In an embodiment of the present invention, the gate electrode 213 of both the pMOS device and then nMOS device is formed from a material having a mid-gap work function between 4.5 and 4.9 eV. In a specific embodiment of the present invention, gate electrode 213 comprises titanium nitride having a work function equal to about 4.7 eV. It should also be appreciated that the gate electrode 213 need not necessarily be a single material, but rather can also be a composite stack of thin films such as a metal/polycrystalline silicon electrode.

As shown in FIGS. 2A and 2B, a pair of source 216 and drain 217 regions are formed in body 206 and body 207 on opposite sides of gate electrode 213. The source region 216 and the drain region 217 are formed of the same conductivity type such as n-type or p-type conductivity, depending on if the transistor is an nMOS device or a pMOS device. In an embodiment of the present invention, source region 216 and drain region 217 have a doping concentration of 1×10¹⁹-1×10²¹ atoms/cm³. Source region 216 and drain region 217 can be formed of uniform concentration or can include subregions of different concentrations or doping profiles such as tip regions (e.g., source/drain extensions).

As shown in FIGS. 2A and 2B, the channel region of the pMOS and nMOS devices is the portion of semiconductor bodies 206 and 207 located between source regions 216 and drain regions 217 under the gate insulator 212 and gate electrode 213. In certain embodiments of the present invention, a pMOS device formed in region 204 has a channel region of undoped SiGe. In other embodiments the channel regions of body 206 and body 207 are doped SiGe. In an embodiment of the present invention, the channel region of semiconductor body 207 is intrinsic or undoped silicon. In another embodiment of the present invention, channel region of semiconductor body 207 is doped silicon. When the channel region is doped, it is typically doped to the opposite conductivity type of the source region 216 and the drain region 217. For example, the nMOS device 205 has source and drain regions which are n-type conductivity while the channel region is doped to p-type conductivity. When channel region is doped, it can be doped to a conductivity level of between 1×10¹⁶ to 1×10¹⁹ atoms/cm³. In certain multi-gate transistor embodiments of the present invention, the pMOS channel regions have an impurity concentration of 10¹⁷ to 10e¹⁸ atoms/cm³.

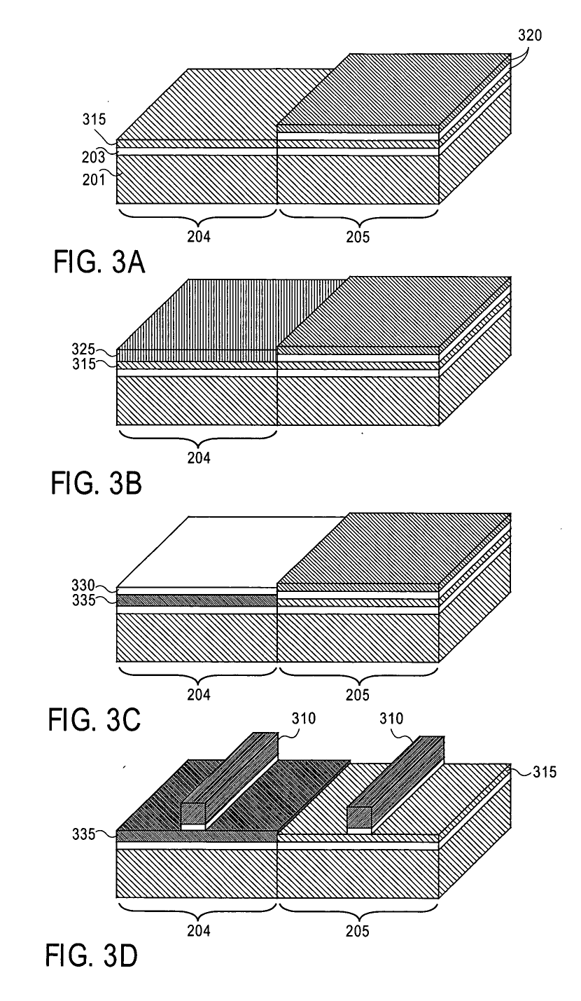

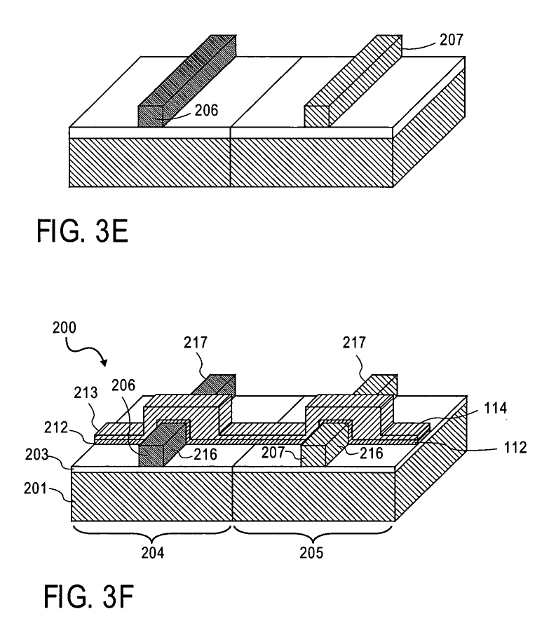

A method of fabricating a CMOS device on an insulating substrate in accordance with an embodiment of the present invention as shown in FIG. 2A is illustrated in FIGS. 3A-3F. Insulating substrate can be formed in any commonly known fashion. In an embodiment of the present invention, shown in FIG. 3A, the insulating substrate includes a lower monocrystalline silicon carrier 201 upon which there is an insulating layer 203, such as a silicon dioxide film or silicon nitride film. Insulating layer 203 isolates semiconductor film 315 from carrier 201, and in an embodiment is formed to a thickness between 200-2000 Å. Insulating layer 203 is sometimes referred to as a “buried oxide” layer and the substrate comprised of 201, 203 and 315 is referred to as a silicon or semiconductor on insulating (SOI) substrate.

Although the semiconductor film 315 is ideally a silicon film, in other embodiments it can be other types of semiconductor films, such as germanium (Ge), a silicon germanium alloy (SiGe), gallium arsenide (GaAs), InSb, GaP, GaSb, or InP. In an embodiment of the present invention, semiconductor film 315 is an intrinsic (i.e., undoped) silicon film. In other embodiments, semiconductor film 315 is doped to p-type or n-type conductivity with a concentration level between 1×10¹⁶-1×10¹⁹ atoms/cm³. Semiconductor film 315 can be in-situ doped (i.e., doped while it is deposited) or doped after it is formed on substrate 202 by for example ion-implantation. Doping after formation enables complementary devices 204 and 205 to be fabricated easily on the same substrate. The doping level of the semiconductor substrate film 315 at this point can determine the doping level of the channel region of the device.

In certain embodiments of the present invention, semiconductor substrate film 315 is formed to a thickness approximately equal to the height desired for the subsequently formed semiconductor body or bodies of the fabricated transistor. In an embodiment of the present invention, semiconductor substrate film 315 has a thickness or height of less than 30 nanometers and ideally less than 20 nanometers. In certain embodiments of the present invention, semiconductor substrate region 315 is formed to a thickness enabling the fabricated transistor to be operated in a fully depleted manner for its designed gate length (Lg).

Semiconductor substrate region 315 can be formed on insulator 203 in any well-known method. In one method of forming a silicon-on-insulator substrate, known as the separation by implantation of oxygen (SIMOX) technique. Another technique currently used to form SOI substrates is an epitaxial silicon film transfer technique generally referred to as bonded SOI.

If desired, a masking can be formed over any regions of the substrate where there is to be no epitaxial semiconductor region subsequently formed on substrate region 315. In a particular embodiment shown in FIG. 3A, mask layer 320 is formed over the region 205. Mask layer 320 can be of any commonly known material capable of surviving the subsequent process of forming the epitaxial semiconductor region. In an embodiment of the present invention, mask layer 320 is a dielectric material capable of serving as a good diffusion barrier, such as silicon nitride. As shown in FIG. 3A, a pad oxide is typically used as a buffer layer between the silicon nitride mask and semiconductor substrate region 315. Commonly known techniques, such as CVD, LPCVD, or PECVD may be used to deposit the mask material. Mask 320 is then selectively defined by commonly known lithography and etch techniques, so that the mask 320 is substantially removed from the region 204. In certain embodiments of the present invention, when the epitaxial semiconductor film 325 is to be formed on all transistors, no mask layer 320 is formed.

An epitaxial semiconductor film 325 is then formed on substrate film 315. In certain embodiments, epitaxial semiconductor film 325 is selectively formed on the substrate region 204 where a pMOS device is desired, as shown in FIG. 3B. Any commonly known epitaxial processes suitable for the particular semiconductor materials can be used to form the semiconductor film 325. In a particular embodiment, an LPCVD process using germane and a silicon source gas, such as a silane, as precursors forms a SiGe film 325 on silicon semiconductor region 315. In a further embodiment, HCl can be utilized during the SiGe growth to improve the selectivity of the growth. Another embodiment comprises a silicon film 325 grown on a SiGe film 315. In yet another embodiment a silicon-carbide film 325 is formed on a silicon film 315. In still another embodiment a silicon film 325 is formed on a silicon-carbide film 315. Film 325 can be grown to have a particular composition determined by the final amount of band offset desired for the transistor. In a particular embodiment of the present invention a silicon-germanium film 325 having about 5 percent to about 30 percent germanium is formed. In other embodiments, the germanium concentration is 50 percent, or more. Ideally, the formation process is capable of producing a single crystalline semiconductor film 325 from the surface of semiconductor substrate film 315. The semiconductor film 325 is grown to the desired thickness, some embodiments including in-situ impurity doping. In certain embodiments where the semiconductor film 325 is not lattice matched to the substrate semiconductor film 315, the maximum thickness is the critical thickness.

Subsequent to the formation of the epitaxial semiconductor film 325, an outdiffusion barrier 330 is formed over film 325. The outdiffusion barrier 330 can be formed from any commonly known material capable of limiting the loss of constituents from the epitaxial semiconductor film 325 during subsequent elevated-temperature processes. While, the outdiffusion barrier 330 need not be directly on or in intimate contact with epitaxial semiconductor film 325, in the particular embodiment shown in FIG. 3C, a thermally grown oxide 330 of the film 325 forms the outdiffusion barrier. In other embodiments, the outdiffusion barrier 330 is formed from a deposited dielectric such as a silicon dioxide, or nitride. In particular embodiments where the film 325 is SiGe having a relatively high germanium concentration, above about 20 percent, the quality of the oxides formed on epitaxial semiconductor film 325 degrades and it becomes more difficult to form a film capable of preventing outdiffusion of germanium. Therefore, in some embodiments of the present invention, the outdiffusion barrier 330 is formed from a high-k dielectric material. The high-k dielectric material used for outdiffusion barrier 330 may be of any commonly known material, such as a metal oxide dielectric, such as to tantalum oxide, titanium oxide, hafnium oxide, zirconium oxide, or aluminum oxide. The high-K film can be formed by well-known techniques, such as chemical vapor deposition (CVD) and atomic layer deposition (ALD).

Next, an elevated-temperature anneal is performed to intermix the constituents of epitaxial film 325 and substrate film 315 into a semiconductor alloy region 335 having the desired band gap and band offsets. In a particular embodiment, the anneal is performed by commonly known techniques, such as rapid thermal anneal (RTP) or furnace anneal, for a time sufficient to uniformly distribute the constituents of film 325 and substrate film 315. Region 335, shown in FIG. 3C, is a single crystal semiconductor having excellent film quality and electronic properties consistent with the alloy formed from epitaxial semiconductor film 325 and substrate film 315. Substrate region 335 then has the desired band gap and offset necessary to provide the desired threshold voltage of the device formed on region 335. In specific embodiments where the outdiffusion barrier 330 is a thermal oxide of film 325, the outdiffusion barrier thickness increases as film 325 is oxidized. Constituents of film 325 oxidized less readily are pushed from the oxidized region 330 to the unoxidized portion of film 325 and underlying substrate film 315. This phenomenon is commonly referred to as condensation. In a particular embodiment of the present invention where film 325 is SiGe and substrate film 315 is silicon, the silicon atoms of 325 oxidize more readily than germanium atoms. Because oxide layers 330 and 203 block germanium from diffusion out of films 325 and 315, the total number of germanium atoms is conserved. Therefore, the final germanium concentration in the alloyed SiGe region 335 is increased up to the ratio of the thickness of epitaxial semiconductor film 325 to that of region 335 multiplied by the initial germanium concentration of epitaxial film 325. In this particular embodiment, a high germanium concentration region 335 can be formed from silicon substrate film 315 to produce a SiGe on an insulator (SGOI) region locally, only where a particular device is to be formed, rather than forming SiGe globally, across the entire substrate.

In a particular embodiment where epitaxial film 325 is SiGe and barrier 330 is a thermal oxide, the anneal is performed for a duration sufficient to completely oxidize the epitaxial film 325, such that the initial substrate film 315 in alloyed form 335 is the only semiconductor region above insulator 203. In a more particular embodiment, film 315 is about 20 nanometers thick with a germanium concentration of about 25 percent after the alloying anneal. In other embodiments where film 325 is SiGe and the outdiffusion barrier 330 is a deposited dielectric, no condensation occurs and the constituents of substrate film 315 and epitaxial film 325 merely interdiffuse, or intermix, and the final thickness of the semiconductor film 335 is the sum of the thickness of substrate film 315 and that of film 325. In certain embodiments of the present invention, various regions of film 325 are selectively masked with an outdiffusion barrier having characteristics enabling film 325 to have different alloy compositions and therefore different band offsets after intermixing. In these embodiments, devices with various voltage threshold characteristics can be achieved on the same substrate. In one such embodiment, an outdiffusion barrier 330 is formed from a deposited oxide, patterned with commonly known methods, and a thermal outdiffusion barrier 330 then formed on the regions of film 325 not covered by the deposited outdiffusion barrier. After intermixing, region 335 formed in areas where film 325 was covered with the deposited oxide would have a different alloy concentration than region 335 formed in areas where film 325 was covered with a thermal oxide and thus, transistors formed in the different alloy regions would have different threshold voltages.

Wells can then be selectively formed for pMOS and nMOS transistors using any commonly known technique to dope regions to a desired impurity concentration. In a certain embodiment of the present invention, outdiffusion barrier 330 and mask 320 are selectively removed from regions 204 and 205 by commonly known methods in a manner that enables selective well implantation without additional lithography. In other embodiments of the present invention, both outdiffusion barrier 330 and mask 320 are removed and commonly known lithography used to selectively form well regions. In embodiments of the present invention, regions 204 and 205 are selectively doped to n-type and p-type conductivity with an impurity concentration level of about 1×10¹⁶-1×10¹⁹ atoms/cm³. In a particular multi-gate transistor embodiment of the present invention, a pMOS channel formed on alloy region 335 has a valence band offset of about 300 mV and an n-type channel impurity concentration level of about 1×10¹⁷-1×10¹⁸ atoms/cm³.

Once films 330 and 320 are removed, a masking layer 310 can be used to define the active regions of the devices in alloyed semiconductor region 335 and non-alloyed semiconductor region 315. The masking layer 310 can be any well-known material suitable for defining the semiconductors 325 and 315. In an embodiment of the present invention, masking layer 310 is a lithographically defined photo resist. In other embodiments, mask 310 is formed of a dielectric material that has been lithographically defined and then etched using commonly known techniques. In the particular embodiment shown in FIG. 3D, masking layer can be a composite stack of materials, such as an oxide/nitride stack. As shown in FIG. 3E, once masking layer 310 has been defined, semiconductor regions 335 and 315 are then defined by commonly any known etching technique to form semiconductor bodies 206 and 207. In certain embodiments of the present invention, anisotropic plasma etches, or RIE, are used to define semiconductor bodies 206 and 207. In a particular embodiment where body 206 is a SiGe alloy and body 207 is silicon, a commonly known plasma etch can be used to delineate both body 206 and body 207 followed by wet etches known in the art to be appropriate for the germanium composition of body 206 and for silicon of body 207. For planar, or single-gate embodiments, the planar devices are merely formed on the films 335 and 315 and mask 310 is used to define isolation regions. In a further embodiment, as shown in FIG. 3E, masking layer 310 is removed from the semiconductor bodies 206 and 207 using commonly known techniques that depend on the material selected for masking layer 310. In other embodiments, such as for particular dual-gate or FinFET designs, masking layer 310 is not removed, so that layer 310 can subsequently provide isolation from the gate electrode 213.

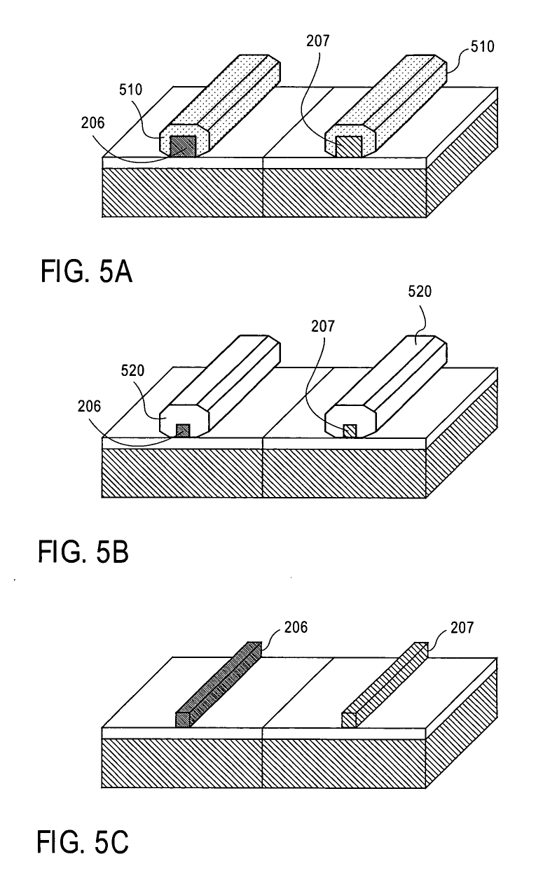

Once the semiconductor bodies 206 and 207 are formed, further processing can be performed to further enhance the body shape, composition or, surface quality. If desired, a method as shown in FIGS. 5A-5C may be performed. As shown in FIG. 5A, a sacrificial film 510 may be formed on the free semiconductor surfaces of bodies 206 and 207. Following the formation of the sacrificial film 510, a thermal oxidation is performed to oxidize the sacrificial film and a portion of the bodies 206 and 207, forming an oxidized region 520. Following the oxidation, the oxidized region 520 is selectively removed by commonly known means such as HF, leaving bodies 206 and 207 with a reduced dimension, as shown in FIG. 5C. The oxidation reduces the dimensions of semiconductor bodies 206 and 207 and the presence of the sacrificial film 510 improves the smoothness and reduces the defect states of the bodies 206 and 207 as compared to merely oxidizing bodies 206 and 207 in absence of the sacrificial layer. In an embodiment, the sacrificial film 510 is an epitaxial semiconductor formed by commonly known techniques, as shown in FIG. 5A. The sacrificial film can be of a same or different material or composition as the bodies 206 and 207. In a particular embodiment, the sacrificial film is silicon. In another particular embodiment, the sacrificial film is a SiGe alloy. In still another embodiment, the film may be a composite region with a buffer SiGe film and a silicon capping film. In certain embodiments, the dimensions of 206 and 207 after oxidation are sublithographic. In a particular embodiment, the oxidation reduces the pre-oxidation thickness and width of semiconductor bodies 206 and 207 by about half. Depending on the composition of the sacrificial film 510, a condensation may occur during thermal oxidation of film 510 thereby changing the final composition of the bodies 206 and 207. In an embodiment, the germanium concentration of SiGe body 206 is increased by the amount of germanium present in film 510 and by the extent of the oxidation performed on the body 206. In certain embodiments, body 206 will have a germanium concentration resulting from the cumulative formation of alloyed region 335 and thermal oxidation of film 510, while body 207 will have a germanium concentration resulting from just the thermal oxidation of the film 510. In a further embodiment, a first pMOS device formed from body 206 will have a first threshold voltage and a second pMOS device formed from body 207 will have a second threshold voltage.

Once the bodies 206 and 207 have been prepared, a gate dielectric layer 212, as shown in FIG. 3F, is formed on each of the semiconductor bodies 206 and 207 in a manner dependent on the type of device (single-gate, dual-gate, tri-gate, etc.). In a tri-gate embodiment of the present invention, a gate dielectric layer 212 is formed on the top surface of each of the semiconductor bodies 206 and 207, as well as on the opposite sidewalls of each of the semiconductor bodies. In certain embodiments, such as dual-gate embodiments, the gate dielectric is not formed on the top surface of bodies 206 and 207. The gate dielectric can be a deposited dielectric or a grown dielectric. In an embodiment of the present invention, the gate dielectric layer 212 is a silicon dioxide dielectric film grown with a dry/wet oxidation process. In an embodiment of the present invention, the gate dielectric film 212 is a deposited high dielectric constant (high-K) metal oxide dielectric, such as tantalum pentaoxide, titanium oxide, hafnium oxide, zirconium oxide, aluminum oxide, or another high-K dielectric, such as barium strontium titanate (BST). A high-K film can be formed by well-known techniques, such as chemical vapor deposition (CVD) and atomic layer deposition (ALD).

As shown in FIG. 3F, a gate electrode 213 is formed on both the pMOS and nMOS devices. In certain embodiments, the same gate electrode material is used for both the pMOS device 204 and nMOS device 205. In an embodiment of the present invention, the gate electrode 213 is formed on the gate dielectric layer 212 formed on the top surface of each of semiconductor bodies 206 and 207 and is formed on the gate dielectric 212 formed on the sidewalls of each bodies 206 and 207. The gate electrode can be formed to a thickness between 200-3000 Å. In an embodiment, the gate electrode has a thickness of at least three times the height of the semiconductor bodies 206 and 207. In an embodiment of the present invention, the gate electrode is a mid-gap metal gate electrode such as, tungsten, tantalum nitride, titanium nitride or titanium silicide, nickel silicide, or cobalt silicide. In an embodiment of the present invention gate electrode 213 is simultaneously formed for both the pMOS device 204 and nMOS device 205 by well-known techniques, such as blanket depositing a gate electrode material over the substrate of and then patterning the gate electrode material for both the pMOS and nMOS devices through photolithography and etch. In other embodiments of the present invention, “replacement gate” methods are used to form both the pMOS and nMOS gate electrodes 213, concurrently or otherwise.

Source regions 216 and drain regions 217 for the transistor are formed in semiconductor bodies 206 and 207 on opposite sides of gate electrode 213, as shown in FIG. 3F. In an embodiment of the present invention, the source and drain regions include tip or source/drain extension regions. For a pMOS transistor, the semiconductor fin or body 206 is doped to p-type conductivity and to a concentration between 1×10¹⁹-1×10²¹ atoms/cm³. For an nMOS transistor, the semiconductor fin or body 207 is doped with n-type conductivity ions to a concentration between 1×10¹⁹-1×10²¹ atoms/cm³. At this point the CMOS device of the present invention is substantially complete and only device interconnection remains.

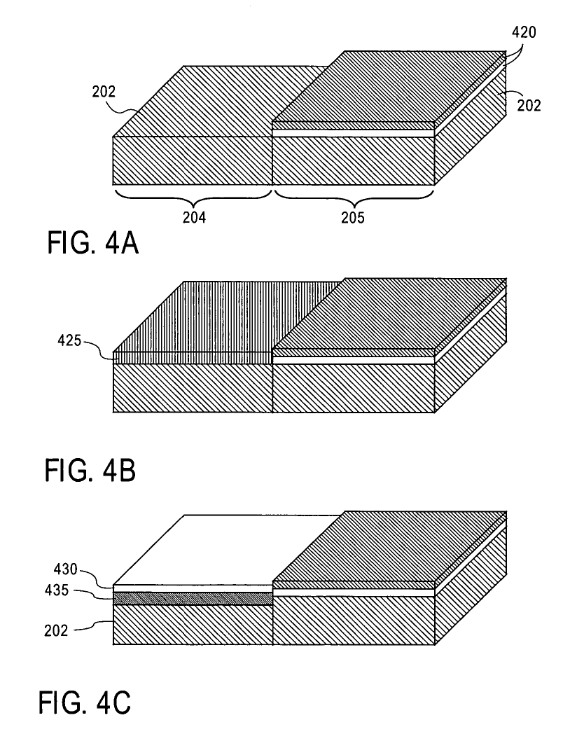

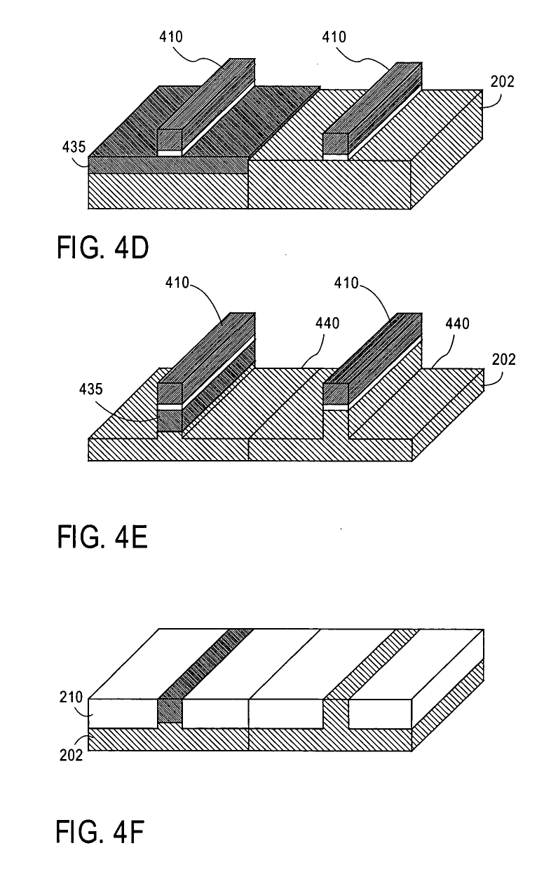

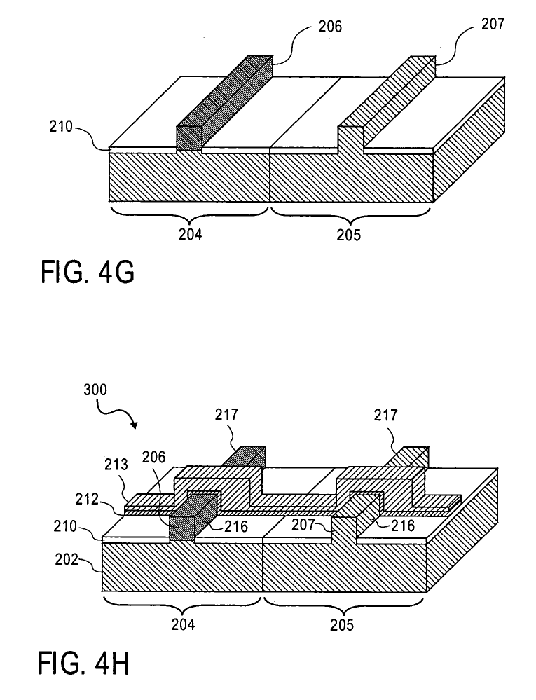

A method of fabricating a CMOS device on a bulk substrate in accordance with an embodiment of the present invention as shown in FIG. 2B is illustrated in FIGS. 4A-4H. The method of fabrication on a bulk substrate in accordance with an embodiment of the present invention is relatively similar to the method of fabrication previously described for an SOI structure in reference to FIGS. 3A-3F. In certain embodiments of the present invention, the substrate 202 of FIG. 4A is a “bulk” semiconductor substrate, such as a silicon monocrystalline substrate or gallium arsenide substrate. In particular embodiments of the present invention, the substrate 202 is a silicon semiconductor substrate having a doped epitaxial region with either p-type or n-type conductivity having an impurity concentration level between 1×10¹⁶-1×10¹⁹ atoms/cm³. In another embodiment of the present invention, the substrate 202 is a silicon semiconductor substrate upon which there is an undoped, or intrinsic epitaxial silicon region.

In embodiments of the present invention, a well region of semiconductor substrate 202 is selectively doped to p-type or n-type conductivity with a concentration level between about 1×10¹⁶-1×10¹⁹ atoms/cm³. Semiconductor substrate 202 can be doped by, for example, ion-implantation enabling both pMOS and NMOS well regions to be fabricated easily on the same substrate. The doping level of the semiconductor substrate 202 at this point can determine the doping level of the channel region of the device.

As shown in FIG. 4A, a masking layer 410, like masking layer 310 in FIG. 3A, is used to define the active regions of the devices 204 and 205 on the bulk semiconductor substrate. The method of forming masking layer 410 can be essentially the same as those described for masking layer 310 of FIG. 3A. Similarly, as shown in FIG. 3B, epitaxial semiconductor film 425 is then formed on the region of substrate 202 not protected by making layer 410, in the same manner as described in reference to FIG. 3B for the SOI substrate.

As shown in FIG. 4C, outdiffusion barrier 430 is formed in the manner described in reference to FIG. 3C. Film 425 is intermixed with a region of semiconductor substrate 202 to form alloyed region 435. Following intermixing, in the embodiment shown in FIG. 4D, the mask 420 and outdiffusion barrier 430 are removed and mask 410 may be formed as described in reference to FIG. 3D. In the embodiment shown in FIG. 4E, the semiconductor regions 435 and 202 are etched using commonly known methods, very similar to those previously described for semiconductor regions 335 and 315 of SOI substrate in reference to FIG. 3E, to form recesses or trenches 440 on the substrate in alignment with the outside edges of masking portion 410. The trenches 440 are etched to a depth sufficient to isolate adjacent transistors from one another. In a particular embodiment, trenches 440 are etched to a depth greater than the thickness of region 435. As shown in FIG. 4F, the trenches 440 are filled with a dielectric to form shallow trench isolation (STI) regions 210 on substrate 202. In an embodiment of the present invention, a liner of oxide or nitride on the bottom and sidewalls of the trenches 440 is formed by commonly known methods, such as thermal oxidation and nitridation. Next, the trenches 440 are filled by blanket depositing an oxide over the liner by, for example, a high-density plasma (HDP) chemical vapor deposition process. The deposition process will also form dielectric on the top surfaces of the mask portions 410. The fill dielectric layer can then be removed from the top of mask portions 410 by chemical, mechanical, or electrochemical, polishing techniques. The polishing is continued until the mask portions 410 are revealed, forming STI regions 210. In an embodiment of the present invention, as shown in FIG. 4F, the mask portions 410 are selectively removed at this time.

In certain embodiments, as shown in FIG. 4G, the STI regions 210 are etched back or recessed to form the sidewalls of the semiconductor bodies 206 and 207 of the device 204 and complementary device 205, respectively. STI regions 210 are etched back with an etchant, which does not significantly etch the semiconductor bodies 206 and 207. In embodiments where semiconductor bodies are silicon and silicon-germanium, isolation regions 210 can be recessed with an etchant comprising a fluorine ion, such as HF. In other embodiments, STI regions 210 are recessed using a commonly known anisotropic etch followed by an isotropic etch to completely remove the STI dielectric from the sidewalls of the semiconductor bodies 206 and 207. STI regions 210 are recessed by an amount dependent on the desired channel width of the transistors formed in 204 and 205. In a particular embodiment, the STI regions 210 are recessed by an amount less than thickness of film 435. In another embodiment of the present invention, STI regions 210 are recessed by approximately the same amount as the width dimension of the top surface of the semiconductor bodies 206 and 207. In other embodiments, the STI regions 210 are recessed by a significantly larger amount than the width dimension of the top surface of the semiconductor bodies 206 and 207. In still other embodiments, the STI regions 210 are not recessed so that planar, or single-gate, devices can be formed.

Once the non-planar semiconductor bodies 206 and 207 are formed on the bulk substrate, the remaining fabrication operations are analogous to those previously described for embodiments on SOI substrates. As described for the SOI embodiments in reference to FIGS. 5A-5C, semiconductor sacrificial region may also be formed on semiconductor bodies 206 and 207 and oxidized, if desired. As shown in FIG. 4H, a gate insulator 212, gate electrode 213, source regions 216, and drain regions 217 are formed on both the device in region 204 and complementary device in region 205 following embodiments analogous to those previously described in the context of an SOI substrate in reference to FIG. 3F. At this point the transistors of the present invention formed on a bulk substrate is substantially complete and only device interconnection remains.

Although the invention has been described in language specific to structural features and/or methodological acts, it is to be understood that the invention defined in the appended claims is not necessarily limited to the specific features or acts described. Rather, the specific features and acts are disclosed as particularly graceful forms of implementing the claimed invention.

We claim:

1. An apparatus comprising:
a first transistor of a first type on a substrate and a second transistor of a type complementary to said first transistor on an alloyed region of said substrate, wherein a gate electrode of said first transistor has substantially the same work function as a gate electrode of said second transistor.

2. The apparatus of claim 1, wherein the band gap of said alloyed region is smaller than that of said substrate.

3. The apparatus of claim 1, wherein said first type is nMOS and said complementary type is pMOS.

4. The apparatus of claim 1, wherein said first transistor and said second transistor have a threshold voltage magnitude less than about 0.7 V.

5. The apparatus of claim 1, wherein said alloyed region is comprised of a silicon-germanium alloy.

6. The apparatus of claim 1, wherein said alloyed region is on an insulating layer of said substrate.

7. The apparatus of claim 1, wherein said gate electrode of said first transistor and said gate electrode of said second transistor have a mid-gap work function between about 4.5 eV and about 4.9 eV.

8. A method, comprising:
forming an epitaxial semiconductor film on a first region of a substrate;
forming an outdiffusion barrier over said epitaxial semiconductor film;
forming an alloy region by alloying said first region with said epitaxial semiconductor film; and
forming a first transistor on said alloy region.

9. The method of claim 8, further comprising:
forming a second transistor, complementary to said first transistor, on a second region of said substrate.

10. The method of claim 8, further comprising:
removing said outdiffusion barrier.

11. The method of claim 8, further comprising:
forming a gate electrode on said first transistor having the same work function as the gate electrode formed on said second transistor.

12. The method of claim 8, wherein said epitaxial semiconductor film comprises a silicon-germanium alloy.

13. The method of claim 8, wherein said first region has a higher germanium concentration after alloying than that of said epitaxial semiconductor film before alloying.

14. The method of claim 8, wherein said outdiffusion barrier comprises a high-k dielectric.

15. The method of claim 8, wherein forming said outdiffusion barrier comprises thermally oxidizing a portion of said first epitaxial semiconductor film.

16. The method of claim 8, wherein said first region has a film thickness less than that of said epitaxial semiconductor film.

17. The method of claim 8, further comprising:
forming a non-planar semiconductor body on said first region by recessing an isolation region adjacent to said first region.

18. The method of claim 8, further comprising:
forming a sacrificial film over a non-planar semiconductor body;
forming a thermally oxidized region by thermally oxidizing said sacrificial film and a portion of said non-planar semiconductor body; and
removing said thermally oxidized region from said non-planar body.

19. The method of claim 18, wherein forming said sacrificial film comprises forming an epitaxial semiconductor film comprised of silicon-germanium buffer and a silicon cap.

20. The method of claim 18, wherein forming said sacrificial film further comprises forming an epitaxial film comprised of silicon.

21. A method comprising:
adjusting a threshold voltage of a pMOS transistor by forming said pMOS transistor on an alloyed portion of a substrate, wherein said alloyed portion has a conduction band offset from a non-alloyed portion of said substrate.

22. The method of claim 21, wherein forming said pMOS transistor further comprises forming said alloyed portion from an alloy of silicon and germanium.

23. The method of claim 21, wherein an nMOS transistor is formed in a non-alloyed portion of said substrate.

24. The method of claim 21, wherein said pMOS transistor gate electrode is formed from the same mid-gap work function material used to form the gate electrode of an nMOS transistor formed on said substrate.
